(19) United States
(12) Patent Application Publication
(10) Pub. No.: US 2019/0132958 A1
(43) Pub. Date: May 2, 2019

(54) METHOD AND SYSTEM FOR LOW TEMPERATURE PRINTING OF CONDUCTIVE METAL ALLOYS

(71) Applicant: Datamax-O'Neil Corporation, Fort Mill, SC (US)

(72) Inventors: Munish Kumar SHARMA, Morris Plains, NJ (US); Chidambaram SP, Morris Plains, NJ (US)

(21) Appl. No.: 16/171,781

(22) Filed: Oct. 26, 2018

(30) Foreign Application Priority Data
Oct. 26, 2017 (IN) 201711037961

(51) Int. Cl. H05K 3/12; H05K 1/02; H05K 1/09

(52) U.S. Cl. CPC H05K 3/1266; H05K 1/028; H05K 1/092; H05K 2201/0257; H05K 2203/0134; H05K 2203/0126; H05K 3/1283

(57) ABSTRACT

System and method of producing on-demand three-dimensional (3D) printed devices on flexible substrates such as paper, plastic, or polymer using metal alloy nanopowders at low temperatures of printing in the range of 150 degrees Celsius (C) to 300 degrees C. The printer disclosed herein may employ a computer-aided design graphics file given as an input to the printer. The printer will selectively release and print the metal alloy nanopowders on select areas on the substrate to form a conductive pattern.

### CROSS REFERENCE TO RELATED APPLICATIONS

This application claims the benefit of Indian Patent Application No. 201711037961 filed Oct. 26, 2017, the disclosure of which is herein incorporated by reference in its entirety.

### FIELD OF THE INVENTION

The present invention relates generally to the field of printing devices, and more particularly to components for a device capable of applying a nanoparticle powder to a substrate.

### BACKGROUND

Printing a conductive circuit on a printed circuit board (PCB) is currently carried out at fairly higher temperatures (˜1000 degrees Celsius (C)). It needs high purity metals and/or alloys for melting and forming the conductive circuits. The higher temperature printing minimizes the choice of substrates, increases the cost, consumes energy and limits the use.

### SUMMARY

Aspects of the disclosure include a method comprising: printing a conductive pattern on a flexible substrate using metal alloy nanopowders, wherein the nanopowders are in the range of approximately 1 nanometers (nm) to approximately 20 nm in diameter; and fusing the nanopowders on the flexible substrate at a temperature ranging from approximately 150 degrees Celsius (C) to 300 degrees C. in a fuser.

Further aspects of the disclosure include a method of forming conductive patterns in a printer comprising: forming metal nanopowder using a flame spray reactor; inputting the nanopowder into an aerosol dispenser; depositing metallic patterns using the nanopowder on a flexible substrate; and fusing the nanopowder to the substrate in a temperature range of approximately 150 degrees Celsius (C) to 300 degrees C.

Further aspects of the disclosure include a method comprising: inputting a conductive pattern into a printer; placing a positive charge on a nanopowder and a photoreceptor drum substantially uniformly by a corona discharge process; activating a laser beam and drawing the conductive pattern on the photoreceptor drum using a mirror assembly and creating a negatively charged pattern of the conductive pattern; sprinkling positively charged nanopowder using a roller on the photoreceptor drum enabling sticking of positively charged nanopowder to the negatively charged pattern on the photoreceptor drum; charging a substrate using a second corona discharge and feeding the substrate near the photoreceptor drum so that the nanopowder on the photoreceptor drum is transferred to the substrate; and feeding the substrate through a hot roller to fuse the nanopowder on the substrate by heat and pressure applied by the hot roller.

The foregoing illustrative summary, as well as other advantages of the invention, and the manner in which the same are accomplished, are further explained within the following detailed description and its accompanying drawings.

### BRIEF DESCRIPTION OF THE DRAWINGS

FIG. 1 is a cross-sectional view showing a conductive pattern forming printer 1 mounted with an exposure device and a photoreceptor drum according to a first embodiment.

FIG. 2 illustrates a block diagram view of a flame-spray process to produce nanopowder. The flame spray process components 2 may either be independent of or integrated into the first embodiment of the printer 1. The flame-spray-printer process produces nanopowder in the size range of approximately 1 to approximately 20 nanometers (nm). The flame spray process components may include a mass flow controller unit, a flow skid unit including valves to flow gases, an aerosol reactor, a pump system, and a metal precursors flow assembly. These components may be connected to a printer cartridge section of the printer 1.

FIG. 3 is a side view of a charge being placed on a photoreceptor drum according to the first embodiment.

FIG. 4 is a perspective view of the photoreceptor drum having an image of the conductive pattern lasered onto according to the first embodiment.

FIG. 5 is a cross-sectional view showing an alternative conductive pattern forming apparatus mounted with a printhead(s) according to a second embodiment.

FIG. 6 is a cross-sectional view showing a blown up portion of the ejection nozzles.

In the drawings, the same or similar components are denoted by the same reference numerals.

### DETAILED DESCRIPTION

In printable and flexible electronics applications, the conductive ink industry uses primarily silver or gold metals at microscale or nanoscale dispersed with the help of non-environment friendly, expensive, and harmful surfactants and stabilizers that go into an ink formulation. Formulation of solution processable conductive inks contain volatile organic content (VOC) and are associated with liquid waste disposal problems. In addition, formulated ink is not stable over a period of time and particulate matter in the ink settles and clogs the nozzle heads of printers used to print conductive patterns. In addition to this, various other techniques used are cold spraying-jet impaction, aerosol deposition by using a pre-heated gas stream, and spray-coating techniques. These technologies often require high capital expenditures and operating expenditures and are not simple to use. In addition, cost of production increases due to annealing in presence of a reducing gas (e.g., hydrogen gas (H₂)/carbon monoxide (CO)) steps post-printing to burn off the solvents and organic matter.

Examples of previous publications in the metal printing industry and the way metal based printing is done today include: using expensive aerosol deposition technology such as U.S. Pat. Nos. 6,277,448 and 8,640,975 and U.S. Patent Application No. 20120094030A1; aerosol nozzle impaction technology such as U.S. Patent Application No. 20140370203A1; and additives-solvent based metal inks such as EP 2253002 A2 and U.S. Pat. Nos. 8,597,420 and 9,187,668. All these patents and patent publications listed above are hereby incorporated by reference in their entirety in this disclosure. The methods disclosed in these publications typically require high capital and operating expenditures to deposit metal based patterns on some form of substrate.

To attain rapid growth in manufacturing sector, it is desired to print conductive metals on flexible substrates such as paper, cloth, polymer and/or plastic which require lower temperatures of printing. The present disclosure addresses this issue by printing metals and alloys at low temperatures. This is attained by directly fusing/fixing metals at nano-dimensions onto the flexible substrates, which happens at much lower temperatures—based on the size of nanopowders. The metals and alloys at nanoscale can be synthesized using a gas phase aerosol method and used directly for printing. As discussed, this way formation of a solution based ink can be eliminated which is non-environment friendly as it uses VOCs and suffers from clogging print heads in the printer.

In this disclosure, many of the challenges above are addressed by simplifying a printing process by use of a nano metal powder without the conversion into conductive ink. This disclosure will help create valuable products at a faster and more cost-effective way via an easier way of printing. It will also lead to increased productivity and better control on printed conductive patterns. This will help pave the way for mass-scale production of conductive printed circuits on paper, plastic etc. that can be further used for making high precision, low cost printed circuit boards (PCBs), printed electronics/printed batteries and next generation Internet of Things (IOT)-edge functionality products in the market.

One aspect of the disclosure is to leverage size dependent properties of small size powders. For nano-size powders (i.e., those in a range of approximately 1 nanometer to approximately 100 nanometers) the melting point depression occurs which is substantially lower than melting point of bulk metal. This is due to high surface area to volume ratio of nanopowders where their surface forces play a vital role in lowering their melting temperatures. Therefore, as the size of a powder particle goes down from bulk to nano-dimensions there is an exponential decay in melting temperatures. Due to this property of metal nanopowders, they melt at low temperatures (e.g., 150 degrees Celsius (C) to 250 degrees C.). The nanopowder can be produced, for example, using a flame spray process as described herein.

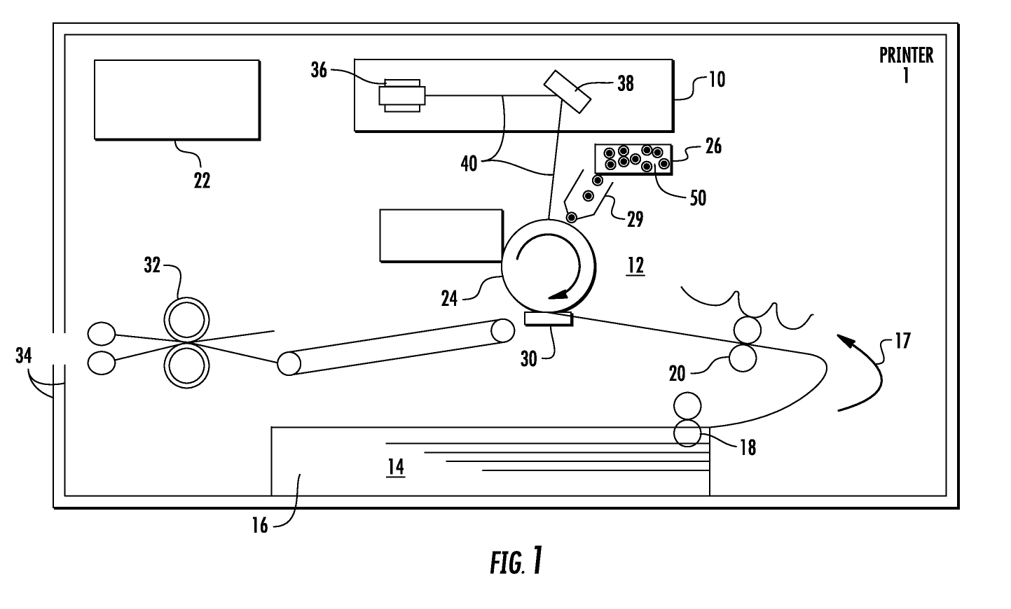

FIG. 1 is a cross-sectional view showing a main part of a printer 1 according to a first embodiment. As shown in FIG. 1, the printer 1 has an exposure device 10 and an image forming unit 12. The image forming unit 12 forms a conductive pattern (or patterns) (e.g., an electrical circuit) on a substrate 14 using, for example, an electrophotographic system. The substrate 14 may be flexible in nature such as paper, plastic, or a polymer. In alternative embodiments, the substrate 14 may be rigid such as a printed circuit board (PCB). The printer 1 has a storage unit 16 storing the substrates 14. In FIG. 1, the storage unit is shown mounted under a photoreceptor drum 24 of the image forming unit 12 and the substrate travel path bends 17 as it advances to the drum 24. However, if the substrate 14 is rigid and would be difficult to bend or it would not be desirous to bend, the storage unit 16 may be located to the side of the drum 24 and follow a direct path which does not bend the substrate 14 during the printing operation. The printer 1 further has a transport unit including a pickup roller 18 and a feed roller 20. The pickup roller 18 picks up the substrates 14 from the storage unit 16 one by one. The feed roller 20 feeds the picked up substrates 14 to the image forming unit 12.

The printer 1 contains a printer processing unit 22 having a central processing unit (CPU) or controller with memory such as read only memory (ROM) and/or random access memory (RAM). The processing unit 22 of the printer 1 processes the image signal containing the conductive pattern(s) to be printed on the substrate 14. The processing unit 22 is connected to a network—either wired or wireless—such as the Internet, a Local Access Network or the like. Processing unit 22 communicates with external devices to receive print data from a computer or other host device. As examples, an electronic file, a feature or a Computer Aided Design (CAD) drawing of a conductive pattern is given as an input to the processing unit 22. The processing unit 22 determines how to correctly display and print this information such as a conductive pattern on a substrate 14. The processing unit 22 is coupled to an exposure device 10.

The exposure device 10 has an optical system such as a light source and a polygon mirror housing 36, an imaging lens (not shown), and a reflecting mirror 38. The light source includes a laser diode (not shown) emitting a laser beam through a collimator lens (not shown) where it converges to the polygon mirror. The polygon mirror rotates to serve as a deflecting portion which deflects a laser beam 40 in a main scanning direction. The laser beam 40 which has passed through imaging lens is applied on a reflection surface of the reflecting mirror 38. The reflecting mirror 38 reflects the laser beam applied thereon toward the photoreceptor drum 24 as an object to be exposed.

The exposure device 10 forms a negatively charged electrostatic latent image on the exposed photoreceptor drum 24 representing a conductive pattern. The laser diode of the exposure device 10 applies a laser beam 40 corresponding to the processed image signal to a photoreceptor drum 24 and thereby exposes the photoreceptor drum 24. The image forming unit 12 has the photoreceptor drum 24, a developer 29 and a transfer charger 30. Cartridge 26 supplies the nanopowders 50 to the image forming unit. The photoreceptor drum 24 rotates around a rotary shaft. The photoreceptor drum 24 is an image carrier on a surface of which the electrostatic latent image corresponding to the image signal is formed by the laser beam applied from the exposure device 10. The cartridge 26 provides the nanopowders 50 to the developer 29 which develops the electrostatic latent image on the photoreceptor drum 24 with the selective release of positively charged nanopowders (or nanoparticles) instead of toner (which will be discussed in detail further below) and thereby forms an image on the photoreceptor drum 23. The developer 29 may use a sheath gas to surround the nanopowder 50 as it is drawn to the negatively charged drum 24. The developer 29 further has a roller for sprinkling positively charged nanopowder on the photoreceptor drum 24 enabling sticking of positively charged nanopowder to the negatively charged conductive pattern on the photoreceptor drum 24. The transfer charger 30 transfers the nanopowder image on the photoreceptor drum 24 onto substrate 14 supplied by the transport unit at proper timing at the transfer position. The substrate 14 is charged using a second corona discharge by the transfer charger 30 so that the nanopowder on the photoreceptor drum is transferred to the substrate 14.

The printer 1 further has a fixing device 32 and a substrate discharge unit 34. The fixing device 32 heats the conductive pattern formed on the substrate 14 in the temperature range of approximately 150 to approximately 300 degrees C. while pressurizing the nanopowder image (or conductive pattern) on the substrate 14 and thus fixes the nanopowder image onto the substrate 14. In some embodiments, the temperature range shall be of approximately 200 to approximately 250 degrees C. The conductive pattern on the substrate 14 can be a flat two-dimensional (2D) pattern or a three dimensional (3D) pattern. The substrate discharge unit 34 is provided on the more downstream side in a substrate transport direction than the fixing device 32. The discharge unit 34 receives the substrate 14 fixed with the nanopowder image and thereafter discharges it outside the printer 1. The printer 1 performs continuous image formation on substrates 14 by repeating the above process.

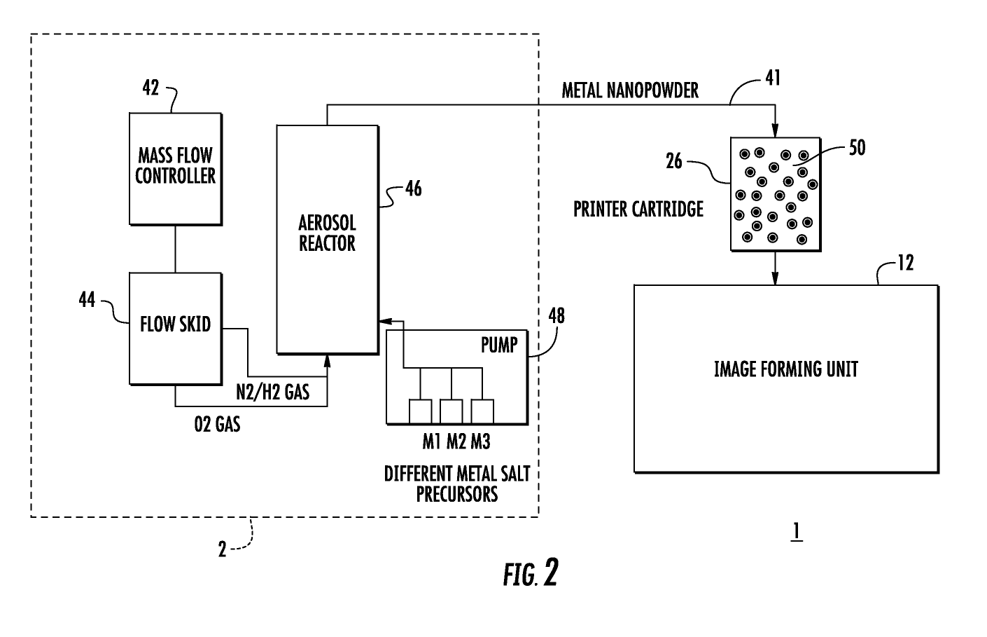

FIG. 2 illustrates a schematic drawing of the components 2 of a flame spray process integrated with the printer 1 of the first embodiment. In one embodiment, the components 2 of the flame spray process will be in a compartment inside printer 1 and can be attached to the printer cartridge 26 in printer 1 by a hose 41. Alternatively, the components 2 could in a separate housing located near the printer 1 and again connected to cartridge 26 by hose 41. The flame spray process components 2 setup produces nanopowder in flame-spray process, collects it and then transfers it to printer cartridge section 26 in the printer 1 shown in FIG. 2. Note that in alternative embodiments, the nanopowders could be prepared by a wet process or a gel method instead of a flame-spray process.

The flame spray process components 2 are described as follows. Mass flow controller 42 controls the flow of gases from flow skid 44 which holds bottles of gases such as, for example, nitrogen (N₂), hydrogen (H₂), and oxygen (O₂). Aerosol reactor 46 is a high temperature heating means (800 degrees C. to 2,000 degrees C.) capable of producing metal nanopowders and alloys using a gas phase thermal spray processes at these high temperatures. The reactor 46 receives inputs from the gases in the flow skid 44 and metal precursor powder from a pump 48 (e.g., syringe pump). The metal precursor is an aqueous solution of various dissimilar metals (M1, M2 and M3). Heating the precursor decomposes it which may form a metal powder that comprises pure metals, metal alloys, intermetallics, and/or metal-containing compounds such as metal oxides and nitrides. The metal precursors are fed to the reactor 46 where the feed materials react under flame to form small size metallic alloys in the form of ultrafine particles or nanopowders. The nanopowders may be any transition elements such as copper (Cu), silver (Ag), tin (Sn), nickel (Ni), gold (Au) or their alloys. The metal and alloy nanopowders of the transition metals may also include for example copper silver (Cu—Ag), copper nickel (Cu—Ni), or copper silver nickel (Cu—Ag—Ni). They may further include other alloys (Mx-Ny) type where x and y are atomic compositions of M and N are individual elements. Further, the nanopowders may be dissimilar metal alloy nanopowders and some bimetallic particles (i.e., dimers, polycrystalline). The alloy composition may also include more than two metals also, in combination at different ratios.

These nanopowders can be produced in size ranges of approximately 1 to approximately 20 nanometers (nm); approximately 1 nm to 14 nm; approximately 2 to approximately 10 nm; and/or approximately 2 to approximately 5 nm. In this disclosure, these ranges are inclusive and the nanopowders can be anywhere in these ranges. This process allows metal nanoparticles to be formed by the flame reactor and then use the particles for three-dimensional (3D) printing without the formation of solution processable/liquid conductive ink. In this range nanopowders have very high surface/volume ratios which help in reducing their bulk melting temperature drastically. This helps in fixing the nanopowders using a hot roller on a flexible substrate in the low temperatures of 150 degrees C. to 300 degrees C. and form conductive patterns while still maintaining high electrical conductivity of approximately 10⁵ to 10⁶ siemens per meter (S/m) which is almost equivalent to bulk metal copper or silver conductivity.

Nanopowder collected from the reactor 46 is transferred to a nanopowder cartridge 26 and then printed. The cartridge 26 shown stores the nanopowder 50 and supplies it on demand for printing. One of the benefits of nanopowder metals is that they have the unique property of melting at much lower temperature than their corresponding bulk material.

Cartridge 26 will receive nanopowders 50 from the aerosol reactor 46 and pass it through developer 29 to the image forming unit 12.

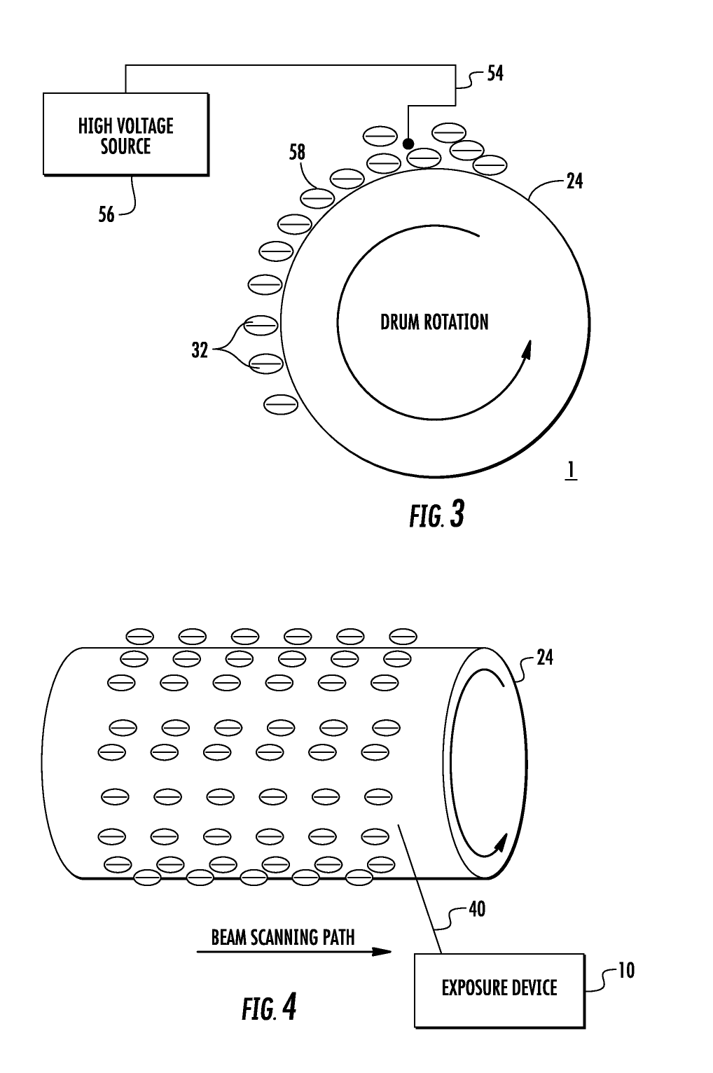

As shown in FIG. 3, a corona wire 54 positioned parallel to the drum 24 receives power from a high voltage power source 56 and projects an electrostatic charge 58 onto the photoreceptor drum 24 which is capable of holding an electrostatic charge on its surface. The processing unit 10 activates a corona discharge from the corona wire 54 to create a positive electric field of megavolts at the tip of the corona wire 54 which gives a static electric charge to anything nearby. The corona discharge charges not only the photoreceptor drum 24 with a positive charge uniformly across its surface but also the nanopowder 50 exiting cartridge 26 and developer 29 with positive charge as well. The residual charge left over by a previous image on the photoreceptor drum 24 is removed by an alternating current (AC) bias voltage. A negative voltage which needs to be uniform is ensured by applying a direct current (DC) bias on the drum surface. The coating inside the photoreceptor drum 24 is composed of a silicon with a photocharging layer sandwiched between a charge leakage layer and a surface layer.

At the same time as the corona discharge from corona wire 54, as shown in FIG. 4, the processing unit 22 activates the laser in exposure device 10 which writes an image pattern onto the surface of the photoreceptor drum 24. Laser beam 40 is targeted at the photoreceptor drum 24, which draws pixels at rates up to sixty-five million times per second. The rotation of photoreceptor drum 24 is such that it continues to rotate during the laser beam sweep, and the angle of sweep is canted by few degrees to compensate for this motion. The laser beam 40 is rapidly turned on and off because of the stream of data held in the printer 1 memory. The laser beam 40 neutralizes (or reverses) the charge on the surface of the drum 24, leaving a static electric negative image on the drum's surface which will attract the positively charged nanopowder particles 50. The areas where laser-beam hits the drum erases the positive charge and creates an area of negative charge instead. The metal powder printing will only take place at negative charge regions and areas with positive charge will remain white.

In developing, a cartridge 26 sprinkles nanopowders 50 onto the photoreceptor drum 24 through a roller. As discussed above, the nanopowder carrying a positive charge is only attracted towards negative charge regions due to electrostatic attraction.

During transferring, a substrate 14 is then rolled under the photoreceptor drum 24, which has been coated with a pattern of nanopowder particles in the exact places where the laser beam 40 struck it moments before. The substrate 14 is given a strong charge using a second corona discharge and moved near photoreceptor drum 24 as shown in FIG. 1. The nanopowder particles 50 have a very weak attraction to both the drum 24 and the substrate 14, but the bond to the drum 24 is weaker and the particles transfer once again, this time from the drum's surface to the substrate surface. The nanopowders 50 are loosely bonded to the substrate 14 and just lie lightly on its surface.

The nanometal image transferred substrate 14 then passes through fuser 32 made up of two hot-rollers which fix the nanopowder image onto substrate 14 by application of heat and pressure. The temperature in this region may be approximately 150 degree C. to approximately 300 degrees C. for melt fixing of nanopowders and completes the printing of metal powder. In other embodiments, the temperature may be approximately 200 degrees C. to approximately 250 degrees C. An aspect of this embodiment is that the metal nanopowder 50 can be printed at very low temperatures without need of any post-annealing at high temperature. Further, these fixing temperatures can be achieved without the need of any modifiers, organic surfactants and/or surface treating agents. Surface modifiers are used to avoid coating surface defects by repelling water and oil as well as providing stain resistance, non-adhesiveness, anti-blocking and slipperiness to the surface.

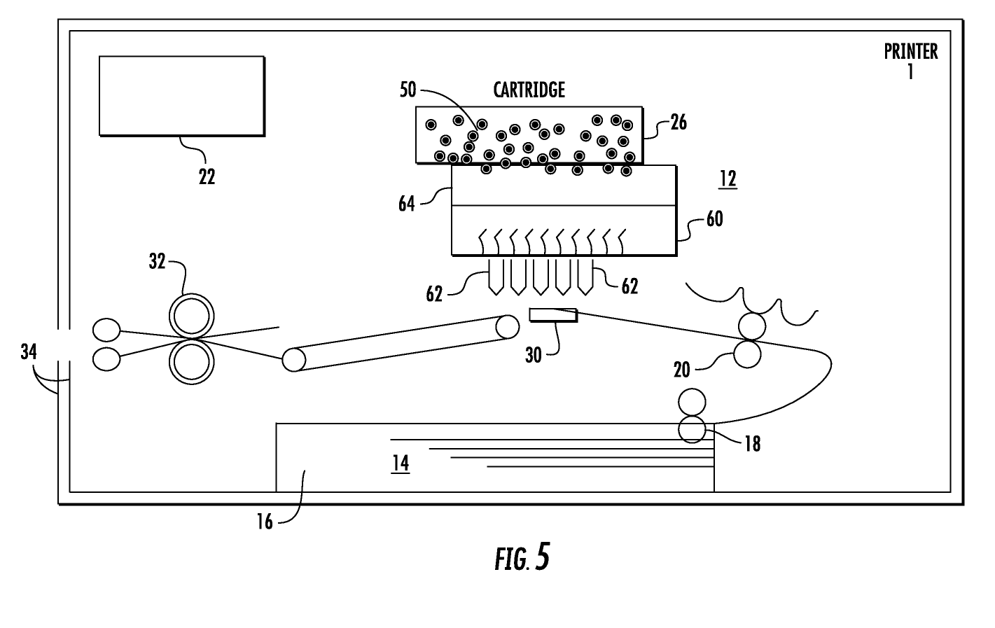

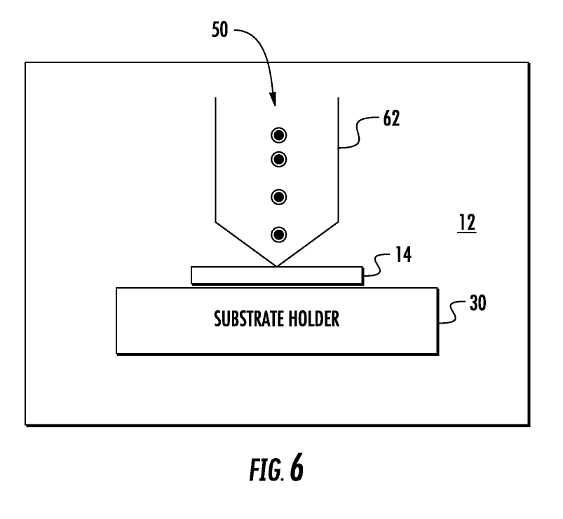

FIGS. 5 and 6 illustrate an alternative embodiment of printer 1. Instead of the image forming unit 12 having a photoreceptor drum 24, printer 1 will use a printhead(s) 60 with a resistive circuit section and nozzles 62 attached to place the conductive pattern on the substrate 14. A controlled supply of nanopowder from cartridge 26 using a sheath gas, usually nitrogen or argon, carries the nanopowder 50 to the nanoparticle melter section 64. In the melter section 64, a uniform temperature is maintained by printhead/resistive heater section 60 which is just sufficient to form a vapor bubble of nanopowder. The sheath gas further carries these vapor bubbles of nanopowder to the nozzle(s) section 62 which creates conductive patterns on the substrate 14. Printheads 60 are generally small electromechanical parts that contain an array of miniature thermal resistors or piezoelectric devices that are energized to eject small droplets of nanopowders out of an associated ejection nozzle 62 or a plurality of nozzles (e.g., an array). The printhead 60 will have firing resistors formed on an integrated circuit chip positioned behind the nanopowder ejection nozzles 62. The ejection nozzles 62 are usually arrayed in columns along the nozzle plate. In operation, referring to FIG. 6, when printer processor unit 22 selectively energizes a firing resistor in the printhead 60, a vapor bubble forms in the ink vaporization chamber, ejecting a drop of nanopowder 50 through nozzle 62 on to the substrate 14. In a piezoelectric printhead, piezoelectric elements are used to eject the nanopowder from a nozzle. Piezoelectric elements located close to the nozzles are caused to deform very rapidly to eject nanopowders 50 through the nozzles 62.

Note that the cartridge 26, printhead(s) 60, nozzles 62 and nanopowder melter 64 may all be one integrated unit or combined in a different manner so that some of the elements are integrated and others are not.

As with the first embodiment of FIG. 1, processing unit 22 of FIG. 5 communicates with a host device or external devices to receive the conductive pattern to be printed. Processing unit 22 controls the movement of cartridge 26 and substrate feed rollers 20. Processing unit 22 is electrically connected to printhead 60 to energize the firing resistors to eject nanopowder 50 on to substrate 14. By coordinating the relative position of cartridge 26 and printhead 60 with substrate 14 and the ejection of nanopowder 50, processing unit 22 produces the desired conductive pattern on substrate 14 according to the conductive pattern inputted.

In FIG. 5, substrate 14 advances in the same manner as the first embodiment shown in FIG. 1. For a stationary printhead(s), feeder rollers 20 may advance substrate 14 continuously past nozzles 62. For a scanning cartridge 26, substrate transport may advance substrate 14 incrementally past nozzles 62, stopping as each swath of the conductive pattern is printed and then advancing substrate 14 for printing the next swath of the conductive pattern. Printhead 60 will print the nanopowders 50 and transfer to substrate 14 placed on substrate holder 30. Thus, a conductive pattern can be printed without use of conductive ink or a high temperature process.

Alternatively, there could be an array of aerosol jets which would be capable of translational motion along one axis. As used in this document: “aerosol” means small liquid or solid particles suspended in air. The aerosol plenum could also be replaced with a bundle of tubes each feeding an individual depositing head. In this configuration, the aerosol jets are capable of independent deposition. In another alternative embodiment, cartridge 26 may include just one or two printheads 60 that scan back and forth on cartridge 10 across the width of substrate 14. A movable cartridge 26 may include a holder for nanopowder melter 62, a guide along which the holder moves, a drive motor, and a belt and pulley system that moves the holder along the guide

Printer 1 may also include an electrostatic aerosol trap and an aerosol absorber located under the substrate 14. An aerosol trap will electrostatically trap, in the area around printhead 60, aerosol generated when nanopowder drops are ejected through the nozzles in printhead 60. The conductors in the aerosol trap are configured to contain much of the aerosol generated during printing in the print zone, forcing many of the particles to collect on uncharged dielectrics. For example, aerosol trapped against the bottom of printhead 60 tends to collect on the uncharged dielectric material that surrounds the nozzle plate. Nanopowder residue collecting in this area may be removed with the service station wiper commonly used in many inkjet printers. Aerosol absorber electrostatically and mechanically absorbs aerosol that escapes the aerosol trap into an array of interconnected conductors positioned beneath the substrate path. The conductors in the absorber form a conductive mesh that helps create a non-uniform electric field extending across the print zone.

In the specification and/or figures, typical embodiments of the invention have been disclosed. The present invention is not limited to such exemplary embodiments. The use of the term “and/or” includes any and all combinations of one or more of the associated listed items. The figures are schematic representations and so are not necessarily drawn to scale. Unless otherwise noted, specific terms have been used in a generic and descriptive sense and not for purposes of limitation.

Devices that are described as in “communication” with each other or “coupled” to each other need not be in continuous communication with each other or in direct physical contact, unless expressly specified otherwise. On the contrary, such devices need only transmit to each other as necessary or desirable, and may actually refrain from exchanging data most of the time. For example, a machine in communication with or coupled with another machine via the Internet may not transmit data to the other machine for long period of time (e.g. weeks at a time). In addition, devices that are in communication with or coupled with each other may communicate directly or indirectly through one or more intermediaries.

Although process (or method) steps may be described or claimed in a particular sequential order, such processes may be configured to work in different orders. In other words, any sequence or order of steps that may be explicitly described or claimed does not necessarily indicate a requirement that the steps be performed in that order unless specifically indicated. Further, some steps may be performed simultaneously despite being described or implied as occurring non-simultaneously (e.g., because one step is described after the other step) unless specifically indicated. Where a process is described in an embodiment the process may operate without any operator intervention.

Recitation of ranges of values herein are merely intended to serve as a shorthand method of referring individually to each separate value falling within the range, unless otherwise indicated herein, and each separate value is incorporated into the specification as if it were individually recited herein. Therefore, any given numerical range shall include whole and fractions of numbers within the range. For example, the range to “1 to 10” shall be interpreted to specifically include whole numbers between 1 and 10 (e.g., 1, 2, 3, . . . 9) and non-whole numbers (e.g., 1.1, 1.2, . . . 1.9).

To supplement the present disclosure, this application incorporates entirely by reference the following commonly assigned patents, patent application publications, and patent applications:
U.S. Pat. Nos. 6,832,725; 7,128,266;
7,159,783; 7,413,127;
7,726,575; 8,294,969;
8,317,105; 8,322,622;
8,366,005; 8,371,507;
8,376,233; 8,381,979;
8,390,909; 8,408,464;
8,408,468; 8,408,469;
8,424,768; 8,448,863;
8,457,013; 8,459,557;
8,469,272; 8,474,712;
8,479,992; 8,490,877;
8,517,271; 8,523,076;
8,528,818; 8,544,737;
8,548,242; 8,548,420;
8,550,335; 8,550,354;
8,550,357; 8,556,174;
8,556,176; 8,556,177;
8,559,767; 8,599,957;
8,561,895; 8,561,903;
8,561,905; 8,565,107;
8,571,307; 8,579,200;
8,583,924; 8,584,945;
8,587,595; 8,587,697;
8,588,869; 8,590,789;
8,596,539; 8,596,542;
8,596,543; 8,599,271;
8,599,957; 8,600,158;
8,600,167; 8,602,309;
8,608,053; 8,608,071;
8,611,309; 8,615,487;
8,616,454; 8,621,123;
8,622,303; 8,628,013;
8,628,015; 8,628,016;
8,629,926; 8,630,491;
8,635,309; 8,636,200;
8,636,212; 8,636,215;
8,636,224; 8,638,806;
8,640,958; 8,640,960;
8,643,717; 8,646,692;
8,646,694; 8,657,200;
8,659,397; 8,668,149;
8,678,285; 8,678,286;
8,682,077; 8,687,282;
8,692,927; 8,695,880;
8,698,949; 8,717,494;
8,717,494; 8,720,783;
8,723,804; 8,723,904;
8,727,223; 8,740,082;
8,740,085; 8,746,563;
8,750,445; 8,752,766;
8,756,059; 8,757,495;
8,760,563; 8,763,909;
8,777,108; 8,777,109;
8,779,898; 8,781,520;
8,783,573; 8,789,757;
8,789,758; 8,789,759;
8,794,520; 8,794,522;
8,794,525; 8,794,526;
8,798,367; 8,807,431;
8,807,432; 8,820,630;
8,822,848; 8,824,692;
8,824,696; 8,842,849;
8,844,822; 8,844,823;
8,849,019; 8,851,383;
8,854,633; 8,866,963;
8,868,421; 8,868,519;
8,868,802; 8,868,803;
8,870,074; 8,879,639;
8,880,426; 8,881,983;
8,881,987; 8,903,172;
8,908,995; 8,910,870;
8,910,875; 8,914,290;
8,914,788; 8,915,439;
8,915,444; 8,916,789;
8,918,250; 8,918,564;
8,925,818; 8,939,374;
8,942,480; 8,944,313;
8,944,327; 8,944,332;
8,950,678; 8,967,468;
8,971,346; 8,976,030;
8,976,368; 8,978,981;
8,978,983; 8,978,984;
8,985,456; 8,985,457;
8,985,459; 8,985,461;
8,988,578; 8,988,590;
8,991,704; 8,996,194;
8,996,384; 9,002,641;
9,007,368; 9,010,641;
9,015,513; 9,016,576;
9,022,288; 9,030,964;
9,033,240; 9,033,242;
9,036,054; 9,037,344;
9,038,911; 9,038,915;
9,047,098; 9,047,359;
9,047,420; 9,047,525;
9,047,531; 9,053,055;
9,053,378; 9,053,380;
9,058,526; 9,064,165;
9,064,165; 9,064,167;
9,064,168; 9,064,254;
9,066,032; 9,070,032;
9,076,459; 9,079,423;
9,080,856; 9,082,023;
9,082,031; 9,084,032;
9,087,250; 9,092,681;
9,092,682; 9,092,683;
9,093,141; 9,098,763;
9,104,929; 9,104,934;
9,107,484; 9,111,159;
9,111,166; 9,135,483;
9,137,009; 9,141,839;
9,147,096; 9,148,474;
9,158,000; 9,158,340;
9,158,953; 9,159,059;
9,165,174; 9,171,543;
9,183,425; 9,189,669;
9,195,844; 9,202,458;
9,208,366; 9,208,367;
9,219,836; 9,224,024;
9,224,027; 9,230,140;
9,235,553; 9,239,950;
9,245,492; 9,248,640;
9,250,652; 9,250,712;
9,251,411; 9,258,033;
9,262,633; 9,262,660;
9,262,662; 9,269,036;
9,270,782; 9,274,812;
9,275,388; 9,277,668;
9,280,693; 9,286,496;
9,298,964; 9,301,427;
9,313,377; 9,317,037;
9,319,548; 9,342,723;
9,361,882; 9,365,381;
9,373,018; 9,375,945;
9,378,403; 9,383,848;
9,384,374; 9,390,304;
9,390,596; 9,411,386;
9,412,242; 9,418,269;
9,418,270; 9,465,967;
9,423,318; 9,424,454;
9,436,860; 9,443,123;
9,443,222; 9,454,689;
9,464,885; 9,465,967;
9,478,983; 9,481,186;
9,487,113; 9,488,986;
9,489,782; 9,490,540;
9,491,729; 9,497,092;
9,507,974; 9,519,814;
9,521,331; 9,530,038;
9,572,901; 9,558,386;
9,606,581; 9,646,189;
9,646,191; 9,652,648;
9,652,653; 9,656,487;
9,659,198; 9,680,282;
9,697,401; 9,701,140;
U.S. Design Pat. No. D702,237;
U.S. Design Pat. No. D716,285;
U.S. Design Pat. No. D723,560;
U.S. Design Pat. No. D730,357;
U.S. Design Pat. No. D730,901;
U.S. Design Pat. No. D730,902;
U.S. Design Pat. No. D734,339;
U.S. Design Pat. No. D737,321;
U.S. Design Pat. No. D754,205;
U.S. Design Pat. No. D754,206;
U.S. Design Pat. No. D757,009;
U.S. Design Pat. No. D760,719;
U.S. Design Pat. No. D762,604;
U.S. Design Pat. No. D766,244;
U.S. Design Pat. No. D777,166;
U.S. Design Pat. No. D771,631;
U.S. Design Pat. No. D783,601;
U.S. Design Pat. No. D785,617;
U.S. Design Pat. No. D785,636;
U.S. Design Pat. No. D790,505;
U.S. Design Pat. No. D790,546;
International Publication No. 2013/163789;
U.S. Patent Application Publication No. 2008/0185432;
U.S. Patent Application Publication No. 2009/0134221;
U.S. Patent Application Publication No. 2010/0177080;
U.S. Patent Application Publication No. 2010/0177076;
U.S. Patent Application Publication No. 2010/0177707;
U.S. Patent Application Publication No. 2010/0177749;
U.S. Patent Application Publication No. 2010/0265880;
U.S. Patent Application Publication No. 2011/0202554;
U.S. Patent Application Publication No. 2012/0111946;
U.S. Patent Application Publication No. 2012/0168511;
U.S. Patent Application Publication No. 2012/0168512;
U.S. Patent Application Publication No. 2012/0193423;
U.S. Patent Application Publication No. 2012/0194692;
U.S. Patent Application Publication No. 2012/0203647;
U.S. Patent Application Publication No. 2012/0223141;
U.S. Patent Application Publication No. 2012/0228382;
U.S. Patent Application Publication No. 2012/0248188;
U.S. Patent Application Publication No. 2013/0043312;
U.S. Patent Application Publication No. 2013/0082104;
U.S. Patent Application Publication No. 2013/0175341;
U.S. Patent Application Publication No. 2013/0175343;
U.S. Patent Application Publication No. 2013/0257744;
U.S. Patent Application Publication No. 2013/0257759;
U.S. Patent Application Publication No. 2013/0270346;
U.S. Patent Application Publication No. 2013/0292475;
U.S. Patent Application Publication No. 2013/0292477;
U.S. Patent Application Publication No. 2013/0293539;
U.S. Patent Application Publication No. 2013/0293540;
U.S. Patent Application Publication No. 2013/0306728;
U.S. Patent Application Publication No. 2013/0306731;
U.S. Patent Application Publication No. 2013/0307964;
U.S. Patent Application Publication No. 2013/0308625;
U.S. Patent Application Publication No. 2013/0313324;
U.S. Patent Application Publication No. 2013/0332996;
U.S. Patent Application Publication No. 2014/0001267;
U.S. Patent Application Publication No. 2014/0025584;
U.S. Patent Application Publication No. 2014/0034734;
U.S. Patent Application Publication No. 2014/0036848;
U.S. Patent Application Publication No. 2014/0039693;
U.S. Patent Application Publication No. 2014/0049120;
U.S. Patent Application Publication No. 2014/0049635;
U.S. Patent Application Publication No. 2014/0061306;
U.S. Patent Application Publication No. 2014/0063289;
U.S. Patent Application Publication No. 2014/0066136;
U.S. Patent Application Publication No. 2014/0067692;
U.S. Patent Application Publication No. 2014/0070005;
U.S. Patent Application Publication No. 2014/0071840;
U.S. Patent Application Publication No. 2014/0074746;
U.S. Patent Application Publication No. 2014/0076974;
U.S. Patent Application Publication No. 2014/0097249;
U.S. Patent Application Publication No. 2014/0098792;
U.S. Patent Application Publication No. 2014/0100813;
U.S. Patent Application Publication No. 2014/0103115;
U.S. Patent Application Publication No. 2014/0104413;
U.S. Patent Application Publication No. 2014/0104414;
U.S. Patent Application Publication No. 2014/0104416;
U.S. Patent Application Publication No. 2014/0106725;
U.S. Patent Application Publication No. 2014/0108010;
U.S. Patent Application Publication No. 2014/0108402;
U.S. Patent Application Publication No. 2014/0110485;
U.S. Patent Application Publication No. 2014/0125853;
U.S. Patent Application Publication No. 2014/0125999;
U.S. Patent Application Publication No. 2014/0129378;
U.S. Patent Application Publication No. 2014/0131443;
U.S. Patent Application Publication No. 2014/0133379;
U.S. Patent Application Publication No. 2014/0136208;
U.S. Patent Application Publication No. 2014/0140585;
U.S. Patent Application Publication No. 2014/0152882;
U.S. Patent Application Publication No. 2014/0158770;
U.S. Patent Application Publication No. 2014/0159869;
U.S. Patent Application Publication No. 2014/0166759;
U.S. Patent Application Publication No. 2014/0168787;
U.S. Patent Application Publication No. 2014/0175165;
U.S. Patent Application Publication No. 2014/0191684;
U.S. Patent Application Publication No. 2014/0191913;
U.S. Patent Application Publication No. 2014/0197304;
U.S. Patent Application Publication No. 2014/0214631;
U.S. Patent Application Publication No. 2014/0217166;
U.S. Patent Application Publication No. 2014/0231500;
U.S. Patent Application Publication No. 2014/0247315;
U.S. Patent Application Publication No. 2014/0263493;
U.S. Patent Application Publication No. 2014/0263645;
U.S. Patent Application Publication No. 2014/0270196;
U.S. Patent Application Publication No. 2014/0270229;
U.S. Patent Application Publication No. 2014/0278387;
U.S. Patent Application Publication No. 2014/0288933;
U.S. Patent Application Publication No. 2014/0297058;
U.S. Patent Application Publication No. 2014/0299665;
U.S. Patent Application Publication No. 2014/0332590;
U.S. Patent Application Publication No. 2014/0351317;
U.S. Patent Application Publication No. 2014/0362184;
U.S. Patent Application Publication No. 2014/0363015;
U.S. Patent Application Publication No. 2014/0369511;
U.S. Patent Application Publication No. 2014/0374483;
U.S. Patent Application Publication No. 2014/0374485;
U.S. Patent Application Publication No. 2015/0001301;
U.S. Patent Application Publication No. 2015/0001304;
U.S. Patent Application Publication No. 2015/0009338;
U.S. Patent Application Publication No. 2015/0014416;
U.S. Patent Application Publication No. 2015/0021397;
U.S. Patent Application Publication No. 2015/0028104;
U.S. Patent Application Publication No. 2015/0029002;
U.S. Patent Application Publication No. 2015/0032709;
U.S. Patent Application Publication No. 2015/0039309;
U.S. Patent Application Publication No. 2015/0039878;
U.S. Patent Application Publication No. 2015/0040378;
U.S. Patent Application Publication No. 2015/0049347;
U.S. Patent Application Publication No. 2015/0051992;
U.S. Patent Application Publication No. 2015/0053769;
U.S. Patent Application Publication No. 2015/0062366;
U.S. Patent Application Publication No. 2015/0063215;
U.S. Patent Application Publication No. 2015/0088522;
U.S. Patent Application Publication No. 2015/0096872;
U.S. Patent Application Publication No. 2015/0100196;
U.S. Patent Application Publication No. 2015/0102109;
U.S. Patent Application Publication No. 2015/0115035;
U.S. Patent Application Publication No. 2015/0127791;
U.S. Patent Application Publication No. 2015/0128116;
U.S. Patent Application Publication No. 2015/0133047;
U.S. Patent Application Publication No. 2015/0134470;
U.S. Patent Application Publication No. 2015/0136851;
U.S. Patent Application Publication No. 2015/0142492;
U.S. Patent Application Publication No. 2015/0144692;
U.S. Patent Application Publication No. 2015/0144698;
U.S. Patent Application Publication No. 2015/0149946;
U.S. Patent Application Publication No. 2015/0161429;
U.S. Patent Application Publication No. 2015/0178523;
U.S. Patent Application Publication No. 2015/0178537;
U.S. Patent Application Publication No. 2015/0178685;
U.S. Patent Application Publication No. 2015/0181109;
U.S. Patent Application Publication No. 2015/0199957;
U.S. Patent Application Publication No. 2015/0210199;
U.S. Patent Application Publication No. 2015/0212565;
U.S. Patent Application Publication No. 2015/0213647;
U.S. Patent Application Publication No. 2015/0220753;
U.S. Patent Application Publication No. 2015/0220901;
U.S. Patent Application Publication No. 2015/0227189;
U.S. Patent Application Publication No. 2015/0236984;
U.S. Patent Application Publication No. 2015/0239348;
U.S. Patent Application Publication No. 2015/0242658;
U.S. Patent Application Publication No. 2015/0248572;
U.S. Patent Application Publication No. 2015/0254485;
U.S. Patent Application Publication No. 2015/0261643;
U.S. Patent Application Publication No. 2015/0264624;
U.S. Patent Application Publication No. 2015/0268971;
U.S. Patent Application Publication No. 2015/0269402;
U.S. Patent Application Publication No. 2015/0288689;
U.S. Patent Application Publication No. 2015/0288896;
U.S. Patent Application Publication No. 2015/0310243;
U.S. Patent Application Publication No. 2015/0310244;
U.S. Patent Application Publication No. 2015/0310389;
U.S. Patent Application Publication No. 2015/0312780;
U.S. Patent Application Publication No. 2015/0327012;
U.S. Patent Application Publication No. 2016/0014251;
U.S. Patent Application Publication No. 2016/0025697;
U.S. Patent Application Publication No. 2016/0026838;
U.S. Patent Application Publication No. 2016/0026839;
U.S. Patent Application Publication No. 2016/0040982;
U.S. Patent Application Publication No. 2016/0042241;
U.S. Patent Application Publication No. 2016/0057230;
U.S. Patent Application Publication No. 2016/0062473;
U.S. Patent Application Publication No. 2016/0070944;
U.S. Patent Application Publication No. 2016/0092805;
U.S. Patent Application Publication No. 2016/0101936;
U.S. Patent Application Publication No. 2016/0104019;
U.S. Patent Application Publication No. 2016/0104274;
U.S. Patent Application Publication No. 2016/0109219;
U.S. Patent Application Publication No. 2016/0109220;
U.S. Patent Application Publication No. 2016/0109224;
U.S. Patent Application Publication No. 2016/0112631;
U.S. Patent Application Publication No. 2016/0112643;
U.S. Patent Application Publication No. 2016/0117627;
U.S. Patent Application Publication No. 2016/0124516;
U.S. Patent Application Publication No. 2016/0125217;
U.S. Patent Application Publication No. 2016/0125342;
U.S. Patent Application Publication No. 2016/0125873;
U.S. Patent Application Publication No. 2016/0133253;
U.S. Patent Application Publication No. 2016/0171597;
U.S. Patent Application Publication No. 2016/0171666;
U.S. Patent Application Publication No. 2016/0171720;
U.S. Patent Application Publication No. 2016/0171775;
U.S. Patent Application Publication No. 2016/0171777;
U.S. Patent Application Publication No. 2016/0174674;
U.S. Patent Application Publication No. 2016/0178479;
U.S. Patent Application Publication No. 2016/0178685;
U.S. Patent Application Publication No. 2016/0178707;
U.S. Patent Application Publication No. 2016/0179132;
U.S. Patent Application Publication No. 2016/0179143;
U.S. Patent Application Publication No. 2016/0179368;
U.S. Patent Application Publication No. 2016/0179378;
U.S. Patent Application Publication No. 2016/0180130;
U.S. Patent Application Publication No. 2016/0180133;
U.S. Patent Application Publication No. 2016/0180136;
U.S. Patent Application Publication No. 2016/0180594;
U.S. Patent Application Publication No. 2016/0180663;
U.S. Patent Application Publication No. 2016/0180678;
U.S. Patent Application Publication No. 2016/0180713;
U.S. Patent Application Publication No. 2016/0185136;
U.S. Patent Application Publication No. 2016/0185291;
U.S. Patent Application Publication No. 2016/0186926;
U.S. Patent Application Publication No. 2016/0188861;
U.S. Patent Application Publication No. 2016/0188939;
U.S. Patent Application Publication No. 2016/0188940;
U.S. Patent Application Publication No. 2016/0188941;
U.S. Patent Application Publication No. 2016/0188942;
U.S. Patent Application Publication No. 2016/0188943;
U.S. Patent Application Publication No. 2016/0188944;
U.S. Patent Application Publication No. 2016/0189076;
U.S. Patent Application Publication No. 2016/0189087;
U.S. Patent Application Publication No. 2016/0189088;
U.S. Patent Application Publication No. 2016/0189092;
U.S. Patent Application Publication No. 2016/0189284;
U.S. Patent Application Publication No. 2016/0189288;
U.S. Patent Application Publication No. 2016/0189366;
U.S. Patent Application Publication No. 2016/0189443;
U.S. Patent Application Publication No. 2016/0189447;
U.S. Patent Application Publication No. 2016/0189489;
U.S. Patent Application Publication No. 2016/0192051;
U.S. Patent Application Publication No. 2016/0202951;
U.S. Patent Application Publication No. 2016/0202958;
U.S. Patent Application Publication No. 2016/0202959;
U.S. Patent Application Publication No. 2016/0203021;
U.S. Patent Application Publication No. 2016/0203429;
U.S. Patent Application Publication No. 2016/0203797;
U.S. Patent Application Publication No. 2016/0203820;
U.S. Patent Application Publication No. 2016/0204623;
U.S. Patent Application Publication No. 2016/0204636;
U.S. Patent Application Publication No. 2016/0204638;
U.S. Patent Application Publication No. 2016/0227912;
U.S. Patent Application Publication No. 2016/0232891;
U.S. Patent Application Publication No. 2016/0292477;
U.S. Patent Application Publication No. 2016/0294779;
U.S. Patent Application Publication No. 2016/0306769;
U.S. Patent Application Publication No. 2016/0314276;
U.S. Patent Application Publication No. 2016/0314294;
U.S. Patent Application Publication No. 2016/0316190;
U.S. Patent Application Publication No. 2016/0323310;
U.S. Patent Application Publication No. 2016/0325677;
U.S. Patent Application Publication No. 2016/0327614;
U.S. Patent Application Publication No. 2016/0327930;
U.S. Patent Application Publication No. 2016/0328762;
U.S. Patent Application Publication No. 2016/0330218;
U.S. Patent Application Publication No. 2016/0343163;
U.S. Patent Application Publication No. 2016/0343176;
U.S. Patent Application Publication No. 2016/0364914;
U.S. Patent Application Publication No. 2016/0370220;
U.S. Patent Application Publication No. 2016/0372282;
U.S. Patent Application Publication No. 2016/0373847;
U.S. Patent Application Publication No. 2016/0377414;
U.S. Patent Application Publication No. 2016/0377417;
U.S. Patent Application Publication No. 2017/0010141;
U.S. Patent Application Publication No. 2017/0010328;
U.S. Patent Application Publication No. 2017/0010780;
U.S. Patent Application Publication No. 2017/0016714;
U.S. Patent Application Publication No. 2017/0018094;
U.S. Patent Application Publication No. 2017/0046603;
U.S. Patent Application Publication No. 2017/0047864;
U.S. Patent Application Publication No. 2017/0053146;
U.S. Patent Application Publication No. 2017/0053147;
U.S. Patent Application Publication No. 2017/0053647;
U.S. Patent Application Publication No. 2017/0055606;
U.S. Patent Application Publication No. 2017/0060316;
U.S. Patent Application Publication No. 2017/0061961;
U.S. Patent Application Publication No. 2017/0064634;
U.S. Patent Application Publication No. 2017/0083730;
U.S. Patent Application Publication No. 2017/0091502;
U.S. Patent Application Publication No. 2017/0091706;
U.S. Patent Application Publication No. 2017/0091741;
U.S. Patent Application Publication No. 2017/0091904;
U.S. Patent Application Publication No. 2017/0092908;
U.S. Patent Application Publication No. 2017/0094238;
U.S. Patent Application Publication No. 2017/0098947;
U.S. Patent Application Publication No. 2017/0100949;
U.S. Patent Application Publication No. 2017/0108838;
U.S. Patent Application Publication No. 2017/0108895;
U.S. Patent Application Publication No. 2017/0118355;
U.S. Patent Application Publication No. 2017/0123598;
U.S. Patent Application Publication No. 2017/0124369;
U.S. Patent Application Publication No. 2017/0124396;
U.S. Patent Application Publication No. 2017/0124687;
U.S. Patent Application Publication No. 2017/0126873;
U.S. Patent Application Publication No. 2017/0126904;
U.S. Patent Application Publication No. 2017/0139012;
U.S. Patent Application Publication No. 2017/0140329;
U.S. Patent Application Publication No. 2017/0140731;
U.S. Patent Application Publication No. 2017/0147847;
U.S. Patent Application Publication No. 2017/0150124;
U.S. Patent Application Publication No. 2017/0169198;
U.S. Patent Application Publication No. 2017/0171035;
U.S. Patent Application Publication No. 2017/0171703;
U.S. Patent Application Publication No. 2017/0171803;
U.S. Patent Application Publication No. 2017/0180359;
U.S. Patent Application Publication No. 2017/0180577;
U.S. Patent Application Publication No. 2017/0181299;
U.S. Patent Application Publication No. 2017/0190192;
U.S. Patent Application Publication No. 2017/0193432;
U.S. Patent Application Publication No. 2017/0193461;
U.S. Patent Application Publication No. 2017/0193727;
U.S. Patent Application Publication No. 2017/0199266;
U.S. Patent Application Publication No. 2017/0200108; and
U.S. Patent Application Publication No. 2017/0200275.

1. A method comprising:
printing a conductive pattern on a flexible substrate using metal alloy nanopowders, wherein the nanopowders are in the range of approximately 1 nanometers (nm) to approximately 20 nm in diameter; and
fusing the nanopowders on the flexible substrate at a temperature ranging from approximately 150 degrees Celsius (C) to 300 degrees C. in a fuser.

2. The method of claim 1, wherein the nanopowders are in the range of approximately 2 to approximately 10 nm in diameter.

3. The method of claim 1, wherein the fusing of the nanopowders on the flexible substrate occurs at a temperature ranging from approximately 200 degrees C. to approximately 250 degrees C. without the use of any of the group consisting of the following: surface modifiers, organic surfactants, and surface treating agents.

4. The method of claim 1, wherein the conductive pattern forms a plurality of metal circuits.

5. The method of claim 1, wherein the nanopowders are from the group consisting of copper (Cu), silver (Ag), tin (Sn), nickel (Ni), gold (Au) and their alloys.

6. The method of claim 1, further comprising: forming the nanopowder in a flame spray reactor.

7. The method of claim 1, wherein the nanopowders are applied to the substrate using an aerosol stream.

8. The method of claim 1, wherein the conductive patterns are received as a computer aided design (CAD) file.

9. The method of claim 1, wherein the printing of the conductive patterns will use a photoreceptor drum.

10. The method of claim 1, wherein the printing of the conductive patterns will use at least one printhead receiving the nanopowder from a cartridge.

11. The method of claim 10, wherein the nanopowders are surrounded by a sheath gas in a nozzle attached to the printhead while transporting to the flexible substrate.

12. The method of claim 1, wherein the nanopowders are supplied from an aerosol reactor.

13. A method of forming conductive patterns in a printer comprising:
forming metal nanopowder using a flame spray reactor;
inputting the nanopowder into an aerosol dispenser;
depositing metallic patterns using the nanopowder on a flexible substrate; and
fusing the nanopowder to the substrate in a temperature range of approximately 150 degrees Celsius (C) to 300 degrees C.

14. The method of claim 13, wherein the fusing of the nanopowder on the flexible substrate occurs at a temperature ranging from approximately 200 degrees C. to approximately 250 degrees C.

15. A method comprising:
inputting a conductive pattern into a printer;
placing a positive charge on a nanopowder and a photoreceptor drum substantially uniformly by a corona discharge process;
activating a laser beam and drawing the conductive pattern on the photoreceptor drum using a mirror assembly and creating a negatively charged pattern of the conductive pattern;
sprinkling positively charged nanopowder using a roller on the photoreceptor drum enabling sticking of positively charged nanopowder to the negatively charged pattern on the photoreceptor drum;
charging a substrate using a second corona discharge and feeding the substrate near the photoreceptor drum so that the nanopowder on the photoreceptor drum is transferred to the substrate; and
feeding the substrate through a hot roller to fuse the nanopowder on the substrate by heat and pressure applied by the hot roller.

16. The method of claim 15, wherein the substrate is a printed circuit board.

17. The method of claim 15, wherein the substrate is a flexible substrate.

18. The method of claim 15, wherein the fuse step occurs at a temperature ranging from approximately 200 degrees C. to approximately 250 degrees C.

19. The method of claim 15, wherein the nanopowder is in the range of approximately 2 to approximately 10 nm in diameter.

20. The method of claim 15, wherein the nanopowder is supplied from an aerosol reactor.
